(19) United States
(12) Patent Application Publication
(10) Pub. No.: US 2002/0019127 A1
(43) Pub. Date: Feb. 14, 2002

(54) Interconnect structure and method of making

(75) Inventor: John H. Givens, Meridian, ID (US)

Correspondence Address: WORKMAN NYDEGGER & SEELEY, 1000 EAGLE GATE TOWER, 60 EAST SOUTH TEMPLE, SALT LAKE CITY, UT, 84111, US

(73) Assignee: Micron Technology, Inc.

(21) Appl. No.: 09/982,191

(22) Filed: Oct. 18, 2001

Related U.S. Application Data
(62) Division of application No. 09/628,524, filed on Jul. 31, 2000.
Application No. 09/628,524 is a continuation of application No. 09/198,738, filed on Nov. 24, 1998, now abandoned.
Application No. 09/198,738 is a continuation of application No. 08/801,810, filed on Feb. 14, 1997, now abandoned.

(51) Int. Cl. H01L 21/4763; H01L 21/44

(52) U.S. Cl. 438/637; 438/618; 438/648; 438/655; 438/656

(57) ABSTRACT

Disclosed is a novel method for forming an interconnect structure to provide electrical communication to an isolated junction on a semiconductor substrate assembly. Under the method, an interconnect structure opening extending through an insulating layer to an exposed surface of a junction is provided and a cobalt layer is deposited in the bottom of the interconnect structure opening. The semiconductor wafer is then annealed to form a cobalt silicide diffusion barrier layer. A titanium layer may be deposited and used as a diffusion membrane prior to the formation of the cobalt silicide diffusion barrier layer. The titanium layer also removes native oxide from the bottom of the interconnect structure opening and is stripped off after cobalt silicide formation. The native oxide may also be cleaned in situ, in which case the cobalt silicide may be directly formed or it may be formed by depositing a seed layer of cobalt followed by the co-deposition of cobalt and silicon, an annealing process, and further cobalt and silicon co-deposition. Diffusion barrier liner layer formation and tungsten metallization follow. The cobalt silicide diffusion barrier layer resulting from the novel method is thinner than prior art diffusion barrier layers, has better epitaxial qualities, and can be sacrificially etched. Cusping and keyholing are reduced and less consumption of silicon from the junction occurs. A low resistance diffusion barrier is formed that is resistant to agglomeration.

This application is a divisional of U.S. patent application Ser. No. 09/628,524, filed on Jul. 31, 2000, which is a continuation of U.S. patent application Ser. No. 09/198,738, filed on Nov. 24, 1998, which is a continuation of U.S. patent application Ser. No. 08/801,810, filed on Feb. 14, 1997, now abandoned, all of which are incorporated herein by reference.

### BACKGROUND OF THE INVENTION

1. The Field of the Invention

The present invention relates to an interconnect structure such as a VLSI contact, via, plug, or trench and to methods of forming the interconnect structure on a semiconductor wafer. More specifically, the present invention is directed to an interconnect structure on a semiconductor substrate assembly and method of making that utilizes a cobalt silicide interface between the interconnect structure and the semiconductor substrate assembly.

2. The Relevant Technology

Recent advances in computer technology and in electronics in general have been brought about at least in part as a result of the progress that has been achieved by the integrated circuit industry in electronic circuit integration and miniaturization. This progress has resulted in increasingly compact and efficient semiconductor devices, attended by an increase in the complexity and numbers with which such semiconductor devices can be formed on a single integrated circuit wafer. The smaller and more complex devices, including resistors, capacitors, diodes, and transistors, have been achieved, in part, by reducing feature size and spacing and by reducing the depth of doped regions known as junctions used in forming the devices. One type of junction is the source/drain region of a MOS transistor that is usually formed together with other source/drain regions in an active area situated upon a semiconductor substrate. The smaller and more complex semiconductor devices have also been achieved by stacking the semiconductor devices or components of the semiconductor devices so that they are situated at various levels on the semiconductor wafer.

Among the semiconductor device components which are being reduced in size are the interconnect structures through which electrical contact is made between discrete components of semiconductor devices located on the varying levels of the semiconductor wafer. These interconnect structures include contacts, vias, plugs, trenches, and other such structures which electrically interconnect semiconductor devices or components of semiconductor devices such as junctions located at nonadjacent levels of an integrated circuit situated on a semiconductor wafer. In order to continue in the process of reducing integrated circuit size, however, new interconnect structure formation methods are required that overcome certain problems existing in the art.

For instance, interconnect structures are generally formed by filling an interconnect structure opening with a conductive filler material in what is known as “metallization.” Interconnect structures have historically been formed using aluminum or aluminum alloy as the metallization material. Aluminum, however, presents the problem of spiking. Spiking occurs when ajunction is being electrically connected by the interconnect structure. Spiking is the dissolution of silicon from the junction into the aluminum metallization material and the dissolution of aluminum metallization material into the junction. Spiking is a result of the tendency of aluminum, when it contacts the silicon of the junction directly at temperatures of about 450° C. or more, to eutectically alloy with the silicon. When such a reaction occurs, the silicon is dissolved into the aluminum. There is a tendency for silicon thus dissolved to be precipitated at a boundary between the metallization layer and the junction as an epitaxial phase. This increases the resistivity across the interconnect structure. The aluminum diffused into the junction also tends to form protruding alloy spike structures that can cause unwanted short circuit conduction between the junction and the underlying silicon substrate.

Interconnect structure openings have more recently been metallized with tungsten in the formation of what is known as a “tungsten plug.” The tungsten plug formation process does not incur spiking, but has proven problematic for other reasons, however, and these problems are heightened by the continuous miniaturization of the integrated circuit and the modern stacked construction of such circuits.

The tungsten plug is typically deposited within a contact hole so as to terminate at a junction. The deposition of the tungsten plug is usually made by a chemical vapor deposition (CVD) process in an atmosphere of fluorine. This type of CVD deposition process attacks silicon so as to create “worm holes” that extend into and possibly through the junction. Worm holes may short out the junction and cause the semiconductor device to fail. A further problem associated with the tungsten plug structure is that the tungsten metallization material does not adhere well directly to silicon or oxide.

These problems have necessitated the use by prior art interconnect structure formation methods of a diffusion barrier liner layer formed between the metallization material and the junction. The diffusion barrier liner layer blocks the reaction between the junction and the metallization material. By way of example, the diffusion barrier liner layer prevents the interdiffusion of silicon and aluminum when aluminum is used as the metallization material. Alternatively, the diffusion barrier liner layer provides a surface to which tungsten in a tungsten metallization process will adhere, while preventing fluorine used in the tungsten CVD process from diffusing into the junction. The diffusion barrier liner layer also absorbs a native oxide layer that forms on the bottom of the interconnect structure opening from exposure to ambient during junction formation and contact etching. The native oxide layer is undesirable in that it blocks a conductive interface from being formed between the bottom of the contact and the surface of the junction that is being electrically interconnected.

Prior art FIGS. 1 through 4 of the accompanying drawings depict one conventional method known in the art for forming an interconnect structure utilizing a diffusion barrier liner layer. The depicted interconnect structure in FIG. 4 comprises a tungsten plug contact. As shown in FIG. 1, a contact opening 18 in which the tungsten plug will be formed is first etched through an insulating layer 16 that overlies a portion of a junction on a silicon substrate 12 of a semiconductor wafer 10. The specific type of depicted junction being electrically interconnected comprises a source/drain region 14 of a MOS transistor. Insulating layer 16 typically comprises a layer of intentionally grown or deposited silicon dioxide such as borophosphosilicate glass (BPSG). Contact opening 18 provides a route for electrical communication between source/drain region 14 and the surface of insulating layer 16.

In a further step, shown in FIG. 2, a titanium layer 22 is sputtered over contact opening 18 to coat the exposed surface of source/drain region 14. Semiconductor wafer 10 is then subjected to a thermal treatment known as annealing in an atmosphere of predominantly nitrogen gas (N2). Titanium layer 22 reacts with source/drain region 14 and a native oxide layer 20 during the thermal treatment. As a result of the reaction, the lower portion of titanium layer 22 overlying source/drain absorbs a portion of the silicon in source/drain region 14 to form a titanium silicide (TiSiₓ) region 24 that is seen in FIG. 3. Concurrently, the upper portion of titanium layer 22 combines with the nitrogen gas of the atmosphere to form an overlying titanium nitride (TiNₓ) layer 26 that is also seen in FIG. 3. A layer of unreacted titanium 22a, which adheres better than titanium nitride, typically remains on the sidewall of contact opening 18. Native oxide layer 20 is absorbed into titanium silicide layer 24 as a result of the thermal treatment. Source/drain region 14 then has formed therein titanium silicide region 24 upon which is situated a titanium nitride layer 26.

Titanium silicide layer 24 provides a conductive interface with the surface of source/drain region 14. Titanium nitride layer 26 formed above titanium silicide layer 24 acts as a diffusion barrier to the interdiffusion of tungsten and silicon, as mentioned above, or to aluminum and silicon when aluminum metallization is employed.

The next step, depicted with its inherent problems shown in FIG. 4, is metallization. In the course of metallization, a conductive filler material is deposited so as to fill up contact opening 18. In tungsten plug formation, this is achieved by a process of a CVD of tungsten to form tungsten layer 28. Titanium nitride layer 26 helps improve the adhesion between the sidewalls of contact opening 18 and the tungsten material of tungsten layer 28 and prevents fluorine used in the CVD of tungsten process from diffusing into source/drain region 14.

One drawback of the tungsten plug structure of the prior art, which becomes increasingly problematic as integrated circuits get more miniaturized and aspect ratios increase, is the poor step coverage provided by conventional tungsten plug formation methods. FIG. 4 depicts the results of a typical deposition of tungsten over titanium nitride layer 26. Poor step coverage causes a narrowing of the mouth of contact opening 18 by a cusping 26a of tungsten layer 28. The narrowing of the mouth of contact opening 18 is known as “bread loafing.” A result of cusping 26a is that contact opening 18 becomes closed off, allowing only partial filling of the metallization material. Partial metallization filling results in a void area, also known as a “keyhole” 28a, that is formed within tungsten layer 28. Keyhole 28a is detrimental because it can open up during further processing steps, where material which could corrode or corrupt tungsten layer 28 enter and fill keyhole 28a. Also, void areas situated within the tungsten layer 28 within contact opening 18 cause an increase in contact resistance.

One reason for the occurrence of cusping 26a is that conventional processes require titanium nitride layer 26 to be formed with a substantial thickness. A large amount of deposited titanium resulting in a substantial thickness of titanium nitride layer 26 is necessary in order to properly form titanium silicide layer 24. High temperatures are necessary in forming titanium silicide, but when titanium silicide is formed at a high temperature and a low thickness, agglomeration occurs. Agglomeration is the occurrence of aggregations of titanium silicide of titanium silicide layer 24 in certain locations on the bottom of contact opening 18 and a lack of titanium silicide at other locations within contact opening 18. Agglomeration raises the contact resistance of the interconnect structure. Higher resistance in turn has a tendency to lower the speed of the semiconductor devices being formed and can result in failure of the entire integrated circuit, especially as resistivities accumulate over large arrays of electrically connected interconnect structures.

The large amount of titanium needed for forming titanium silicide layer 24 is further detrimental in that it also consumes a large amount of silicon from source/drain region 14 in forming titanium silicide layer 24. This is problematic due to the shallowness with which such junctions are being formed as miniaturization levels become more aggressive. The consumption of silicon within a junction causes the junction to become depleted. In turn, the junction depletion will cause leakage of charge therefrom. Leakage from multiple junctions, when aggregated over arrays of similar junctions with electrically connected interconnect structures, can cause the integrated circuit to fail to perform its intended function.

Thus, it is apparent that a method for forming an interconnect structure is needed that overcomes the problems existing in the prior art. By way of example, an improved method is needed to form an interconnect structure with a diffusion barrier liner layer that sufficiently reduces cusping and keyholing when filling a contact opening with a conductive material. Such an improved method is also needed that forms an interface to the junction with a desirable resistivity and that does not deplete the junction, but which forms a desirable diffusion barrier to prevent junction depletion. Such an improved method should also be compatible with current process flows and should not significantly increase the cost or complexity of the process flow.

### SUMMARY OF THE INVENTION

The present invention seeks to resolve the above and other problems which have been experienced in the art. More particularly, the present invention constitutes an advancement in the art by providing a novel interconnect structure on a semiconductor substrate assembly and a novel method for forming the interconnect structure. A substrate assembly is defined herein as a substrate having one or more layers or structures formed thereon.

Under the inventive method, a first step in the formation of the novel interconnect structure comprises providing an interconnect structure opening. The interconnect structure opening typically extends through an insulating layer down to a portion of a sublayer that is desired to be provided with electrical communication such as a junction on a silicon substrate.

A cobalt silicide region is then formed at a bottom of the interconnect structure opening and a conductive filler material is deposited over the cobalt silicide region. Typically, a diffusion barrier liner layer is also deposited over the cobalt silicide region prior to depositing the conductive filler material. The bottom of the interconnect structure opening must be cleaned of a native oxide layer and other impurities prior to forming the cobalt silicide region. Several embodiments are provided for cleaning the bottom of the interconnect structure opening and for forming the cobalt silicide region.

In one embodiment, a titanium layer is deposited on the inside surfaces of the interconnect structure opening after the interconnect structure opening is formed. A thermal treatment is then conducted sufficient to react the titanium layer with the oxygen of the native oxide layer and absorb the oxygen into the titanium layer. Thereafter, a cobalt layer is deposited with a preferred thickness in a range from about 50 Å to about 100 Å. A further thermal treatment is conducted to cause cobalt material from the cobalt layer to migrate through the titanium and oxygen to react with silicon in the source/drain region under the bottom of the interconnect structure opening and form a region that is substantially composed of stoichiometric cobalt silicide. The titanium and oxygen are left on the surface of the bottom of the interconnect structure opening.

The titanium and oxygen as well as unreacted cobalt located on the sidewall of the interconnect structure opening are then removed with a suitable stripping process. The cobalt silicide region remains at the bottom of the interconnect structure opening where it forms a conductive interface with the source/drain region or other sublayer situated on the substrate assembly.

An optional step in the aforedescribed first embodiment is to form a diffusion barrier liner layer over the cobalt silicide region. This is achieved in one embodiment by depositing a thin layer of titanium and an overlying layer of titanium nitride in the interconnect structure opening. The titanium and titanium nitride layers each have a preferred thickness of between about 50 and 500 Å, and collectively form a thinner diffusion barrier liner layer than that provided by the prior art processes discussed above. The conductive filler material is then deposited. Tungsten is a preferred conductive filler material.

A second embodiment of the invention utilizes an in situ preclean to remove a native oxide layer from the surface of the bottom of the interconnect structure opening. The in situ preclean can be conducted with any suitable process. Wet or vapor etching and hydrogen cleaning are examples of preferred in situ preclean processes. In a further step of the second embodiment, a seed layer of cobalt is deposited with a preferred thickness in a range from about 2 Å to about 4 Å upon the side wall of the interconnect structure opening. A co-deposition of cobalt and silicon is thereafter conducted to result in a cobalt and silicon layer with a preferred thickness in a range from about 7 Å to about 14 521 upon the side wall of the interconnect structure opening. A thermal treatment is conducted to react the seed layer and the cobalt and silicon layer and begin the process of forming a region that is substantially composed of stoichiometric cobalt silicide. A further co-deposition of cobalt and silicon is thereafter conducted, after which a further thermal treatment is conducted so as to transform the aggregated cobalt and silicide into yet another region that is substantially composed of stoichiometric cobalt silicide. Cobalt and silicon situated on the sidewall of the interconnect structure that has not reacted to form cobalt silicide can then be stripped with a stripping process that is selective to cobalt silicide. The result is a region situated at the bottom of the interconnect structure opening that is substantially composed of stoichiometric cobalt silicide. A diffusion barrier liner layer and the conductive filler material are then deposited, as was discussed above with respect to the first embodiment, to complete the interconnect structure.

A third embodiment of the invention also utilizes an in situ preclean to remove a native oxide layer from the bottom of the interconnect structure opening. A cobalt layer is thereafter deposited. The cobalt layer can be quite thin due to the lack of titanium between it and the underlying silicon of the source/drain region or other sublayer. Preferably the cobalt layer is deposited with a thickness in a range from about 50 Å to about 100 Å. A thermal treatment is then conducted to transform the cobalt into a region that is substantially composed of stoichiometric cobalt silicide. Excess cobalt that has not reacted to form a silicide thereof can thereafter be easily stripped using an etching process that is selective to cobalt silicide as discussed above. A diffusion barrier liner layer and a conductive filler material are then deposited as discussed for the first embodiment to complete the interconnect structure.

The resultant interconnect structure with respect to the above-discussed embodiments is formed with a thin cobalt silicide region that is a smooth epitaxial film with high epitaxial integrity and high conductivity. The cobalt silicide region forms a conductive interface to the junction without depleting the junction. Leakage and agglomeration are thereby avoided, allowing a shallower junction to be used. The novel process utilizes a diffusion barrier liner layer that has a desired thickness, in conjunction with cobalt silicide, the result of which is a maintenance of consistent step coverage and avoidance of partial metallization filling of high aspect ratio interconnect structure openings, such that the problems of bread loafing and keyholes can be avoided.

### BRIEF DESCRIPTION OF THE DRAWINGS

A more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 is a partial cross-sectional view of a semiconductor substrate assembly depicting the result of a first step of a method, comprising forming a contact opening through an insulative layer to expose a junction on the semiconductor substrate assembly.

FIG. 2 is a partial cross-sectional view depicting the result of a next step in the method of processing the structure seen in FIG. 1, comprising depositing a layer of titanium into the contact opening.

FIG. 3 is a partial cross-sectional view depicting the result of a next step of a prior art method of processing the structure seen in FIG. 2, comprising annealing the titanium layer in a nitrogen gas atmosphere and depositing a cobalt layer in the contact opening.

FIG. 4 is a partial cross-sectional view depicting the result of a next step in the prior art method of processing the structure seen in FIG. 3, comprising depositing a conductive filler material over the contact opening, the titanium silicide region, and the titanium nitride layer. FIG. 4 also illustrates a typical problem encountered in the prior art method when producing a contact, which is the formation of a cusp at the top of the contact opening, as well as a keyhole at the center thereof.

FIG. 5 is a partial cross-sectional view depicting an example of the result of first steps in a first embodiment of the invention of processing the structure seen in FIG. 2, and comprising depositing a layer of cobalt over a layer of titanium previously deposited in the bottom of a contact opening.

FIG. 6 is a partial cross-sectional view depicting an example of a result of first steps in a second embodiment of the invention of processing the structure seen in FIG. 2, comprising conducting an in situ preclean, depositing a thin layer of cobalt, and co4 depositing a layer of cobalt and silicon into the contact opening.

FIG. 7 is a partial cross-sectional view depicting an example of a result of further steps in the second embodiment of the invention of processing the structure seen in FIG. 6, comprising thermally treating the semiconductor wafer and co-depositing a further layer of cobalt and silicon into the contact opening.

FIG. 8 is a partial cross-sectional view depicting an example of a result of first steps in a third embodiment of the method of the present invention of processing the structure seen in FIG. 2, comprising conducting an in situ preclean and depositing a layer of cobalt into the contact opening.

FIG. 9 is a partial cross-sectional view depicting an example of a result of further steps in the first, second, and third embodiments of the method of the present invention of processing the structure seen, respectively, in FIGS. 5, 7, and 8, and comprising annealing the titanium and cobalt layers to form a resulting cobalt silicide, as well as stripping the titanium and unreacted cobalt to leave only the cobalt silicide in the bottom of the contact opening.

FIG. 10 is a partial cross-sectional view depicting the result of further steps in the first, second, and third embodiments of the method of the present invention of processing the structure seen in FIG. 9, and comprising depositing a titanium nitride diffusion barrier liner layer over the cobalt suicide in the bottom of the contact opening.

FIG. 11 is a partial cross-sectional view depicting the result of further steps in the first, second, and third embodiments of the method of the present invention of processing the structure seen in FIG. 10, and comprising depositing a conductive filler material into the contact opening.

### DETAILED DESCRIPTION OF THE INVENTION

A more detailed discussion of the present invention will now be made by referring to FIGS. 1, 2, and 5 through 11 of the accompanying drawings. Therein are illustrated representative embodiments of the method of the present invention for forming an interconnect structure. The interconnect structure of the present invention is used to provide electrical communication between discrete semiconductor devices or components of semiconductor devices which are located on nonadjacent levels of a semiconductor substrate assembly. It is intended herein that a substrate assembly be construed to mean one or more layers or structures upon a substrate.

In the depicted embodiments, the interconnect structure being formed comprises a tungsten plug contact extending through a dielectric layer down to a junction formed on a silicon substrate assembly. The junction comprises a source/drain region of a MOS transistor formed in the silicon substrate assembly. Typically, metal interconnect lines are later formed on a top surface of the interconnect structure to electrically connect the interconnect structure with other electrical devices and structures, some of which may be situated on a different level of the silicon substrate assembly.

The initial steps of the method of the present invention are similar to those of the prior art. Thus, as shown in FIG. 1, a preliminary step comprises providing a silicon wafer 10, which has provided thereon a substrate assembly. In the depicted embodiments, the substrate assembly comprises a silicon substrate assembly 12. A portion of a junction on silicon substrate assembly 12 such as a source/drain region 14 is formed in silicon substrate assembly 12, and an insulating layer such as a BPSG layer 16 is formed over source/drain region 14. An interconnect structure opening in the form of a contact opening 18 is then formed through BPSG layer 16 down to source/drain region 14.

A further step of the method of the present invention comprises the removal of a native oxide layer 20 that typically forms on the bottom of contact opening 18 over source/drain region 14. Native oxide layer 20 forms from exposure to an oxygen containing ambient during the formation of source/drain region 14, and contact etching as discussed above. After removal of native oxide layer 20, a cobalt silicide region is formed at the bottom of contact opening 18, after which a diffusion barrier liner layer is formed and a conductive filler material is deposited to complete the contact. The steps conducted in the cleaning of native oxide layer 20 and the formation of the cobalt silicide region will be further explained in greater detail by discussion of three representative embodiments of the method of the present invention.

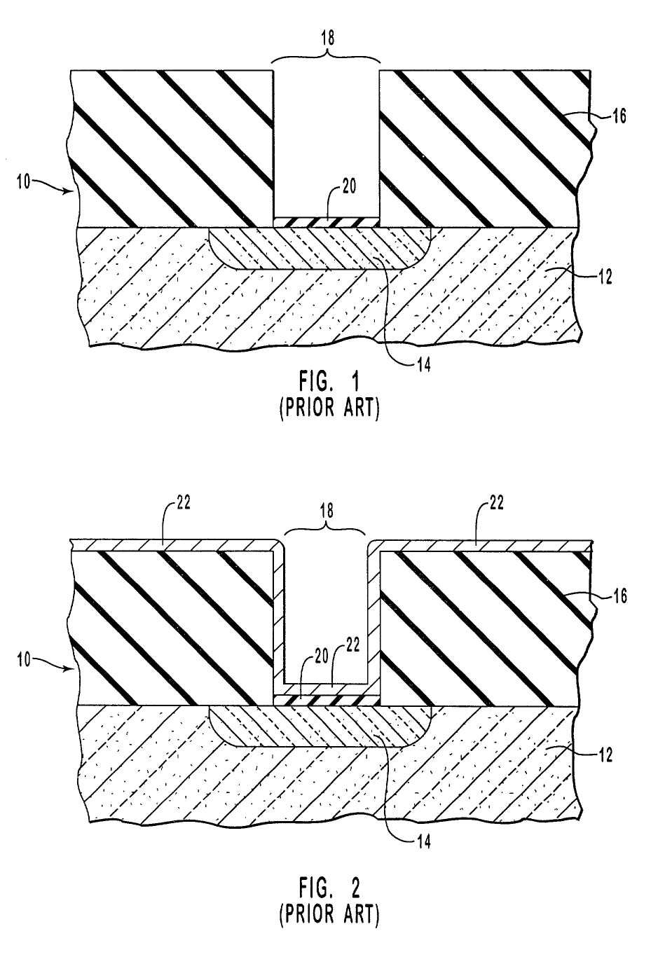

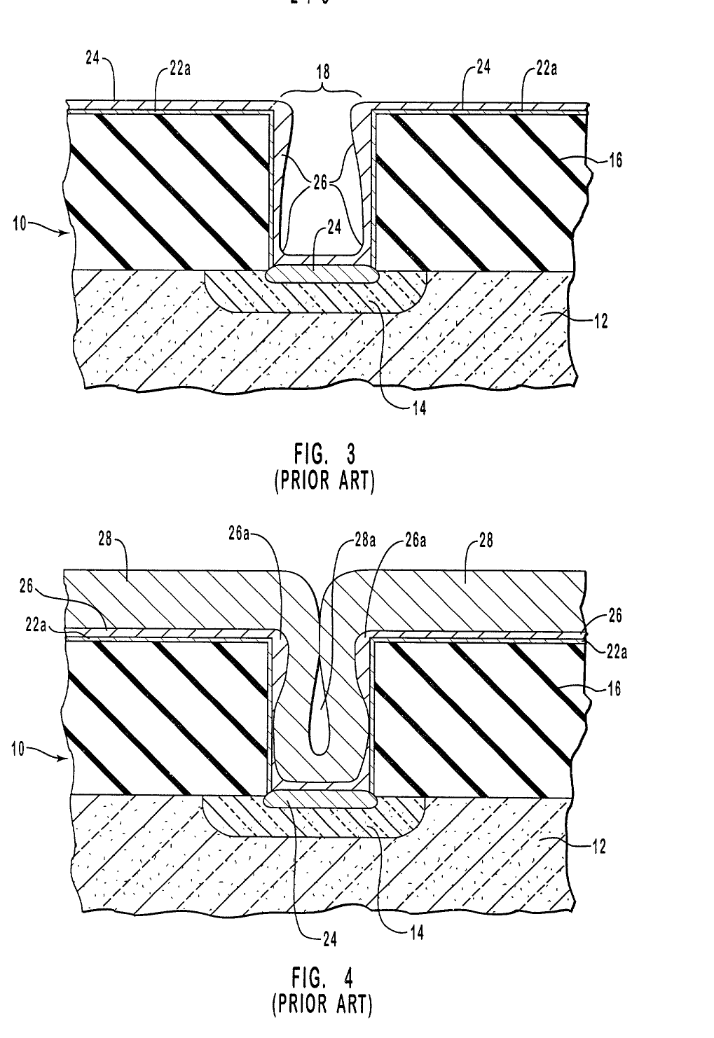

A first embodiment is illustrated in the collection of FIGS. 1, 2, 5, and 9 through 11. In this first embodiment, as in the prior art, cleaning of native oxide layer 20 is achieved as shown in FIG. 2 by depositing a titanium layer 22 to pre-treat the bottom of contact opening 18. Titanium layer 22 is deposited using any suitable method, typically CVD or physical vapor deposition (PVD), and is thereafter subjected to a thermal treatment sufficient to react the titanium and underlying native oxide layer 20, as shown in FIG. 5. The thermal treatment can comprise rapid thermal processing (RTP), and can also comprise annealing in a tube furnace or any other suitable type of thermal treatment. One preferred type of thermal treatment, given by way of example, is RTP conducted at a temperature of about 700° C. for a time period in a range from about 1 second to about 60 seconds and most preferably for about 30 seconds. In so doing, native oxide layer 20 and other impurities such as carbon are absorbed into and bound to titanium layer 22.

Thereafter, as shown in FIG. 5, a cobalt layer 30 is deposited, preferably with a thickness in a range from about 50 Å to about 500 Å. A more preferred thickness is in a range from about 50 Å to about 100 Å. Cobalt in cobalt layer 30 is a mobile atom that forms cobalt silicide in a reaction with silicon that is consumed from source/drain region 14. The silicide of cobalt forms at a lower temperature than titanium silicide. An advantage of a lower silicide formation temperature is that a layer of cobalt silicide can be formed that has a desirably thin thickness. The thickness of cobalt layer 30, as expressed above, avoids agglomeration and consumes a desirably small amount of silicon from source/drain region applications. As such, source/drain region 14 is preserved from an undesirable degree of depletion. In general, an optimally low degree of depletion of a junction reduces junction leakage and makes the inventive process desirably compatible with shallow junction applications. As referred to herein, a shallow junction has a depth in a range from about 500 Å to about 2000 Å.

The use of cobalt metallization in forming the contact does present certain challenges, as cobalt is a magnetic material and is difficult to sputter in a directional manner. Nevertheless, many new sputtering techniques are available to assist in cobalt deposition. For example, high density plasma processes and low pressure applications can be used to increase ionization efficiency. Electrical grids, biased substrates, magnetic enhancement, and other methods to enhance the directionality of the sputtering process can also be used. Additionally, cobalt layer 30 can be deposited from a precursor material with in CVD process.

After depositing cobalt layer 30, semiconductor wafer 10 is again subjected to a thermal treatment. The thermal treatment is preferably conducted as an RTP process with a temperature in a range from about 400° C. to about 600° C., for a time in a range from about 1 second to about 60 seconds, and most preferably for a time of about 30 seconds. The RTP process drives titanium and oxygen material to the exposed surface at the bottom of the interconnect structure opening. Thermal treatments other than an RTP process may also be used. Titanium layer 22 acts as a diffusion membrane. Cobalt atoms in cobalt layer 30, 23 which are the mobile atoms in the reaction, diffuse through the titanium and oxygen molecules of titanium layer 22 into source/drain region 14. The titanium of titanium layer 22, together with the bound up oxygen of native oxide layer 20, are left on the exposed surface of titanium layer 22.

As seen in FIG. 5, the thermal treatment that reacts the titanium of titanium layer 22 and underlying native oxide layer 20 can be conducted for a sufficient time period and at a sufficient temperature so that a region of titanium suicide is formed under titanium layer 22 or in place of titanium layer 22 in the area indicated at reference numeral 25. If this occurs, it is more difficult to diffuse the cobalt atoms of cobalt layer 30 through the resultant titanium silicide material at area 25 so as to react the cobalt atoms with the silicon of underlying source/drain region 14 and thereby form cobalt silicide. In order to do so, however, the thermal treatment which reacts the cobalt atoms of cobalt layer 30 and underlying silicon of source/drain region 14 should be conducted as a RTP process at a temperature in a range from about 550° C. to about 750° C. and for a time period in a range from about 1 second to about 60 seconds. More preferably, the thermal treatment will be conducted as a RTP process at a temperature of about 650° C. and for a time period of about 30 seconds.

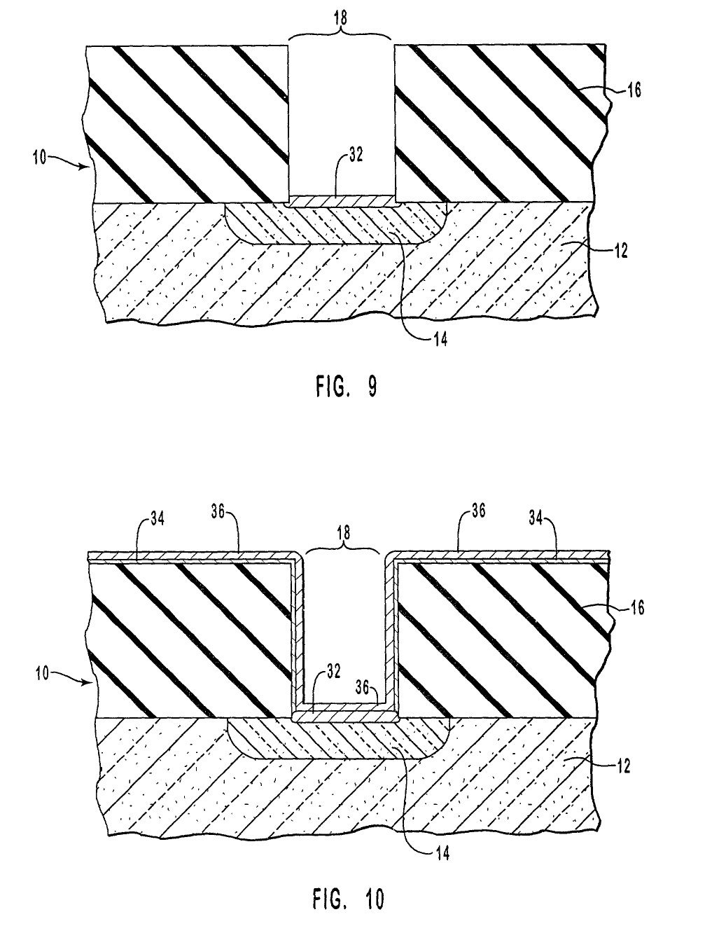

During the thermal treatment of the structure seen in FIG. 5, cobalt layer 30 is transformed to a cobalt silicide region 32 which is substantially composed of stoichiometric cobalt silicide as shown in FIG. 9. Titanium and oxygen atoms that had been bound to the titanium in titanium layer 22 are then removed. Several suitable and well known processes exist for removing these bound titanium and oxygen atoms, each of which will preferably be selective to cobalt silicide of cobalt silicide region 32 so as to substantially prevent the removal thereof. For example, an in situ clean using hydrofluoric acid can be conducted, or a “piranha clean,” of wet dipping with a peroxide sulfuric acid solution that modifies the bound titanium and oxygen atoms into a gaseous phase that is then removed. The piranha clean is preferably conducted with H₂SO₄ and H₂O₂ at a concentration in a range from about 1 to about 3. The stripping process also removes cobalt that has not been silicided, such as the cobalt deposited on the silicon dioxide material making up the sidewall of BPSG layer 16 defining contact opening 18.

Thereafter, as shown in FIG. 10, a titanium nitride diffusion barrier layer 36 is formed over cobalt silicide region 32 in contact opening 18 and functions to provide a basis for blanket nucleation of a later deposited tungsten layer. Titanium nitride diffusion barrier layer 36 also prevents diffusion of fluorine from a later tungsten deposition process. A titanium layer 34 with a thickness in a range from about 100 A to about 500 A is typically formed under titanium nitride diffusion barrier layer 36 in order to provide adhesion to the silicon dioxide material making up the sidewall of BPSG layer 16 defining contact opening 18. The thickness of titanium nitride diffusion barrier 36 can also be minimal, due to the prior formation of cobalt silicide region 32, and preferably has a thickness in a range from about 100 Å to about 500 Å. As titanium layer 34 and titanium nitride diffusion barrier layer 36 are not necessary to forming a silicide, they can be formed as thin as the forgoing range.

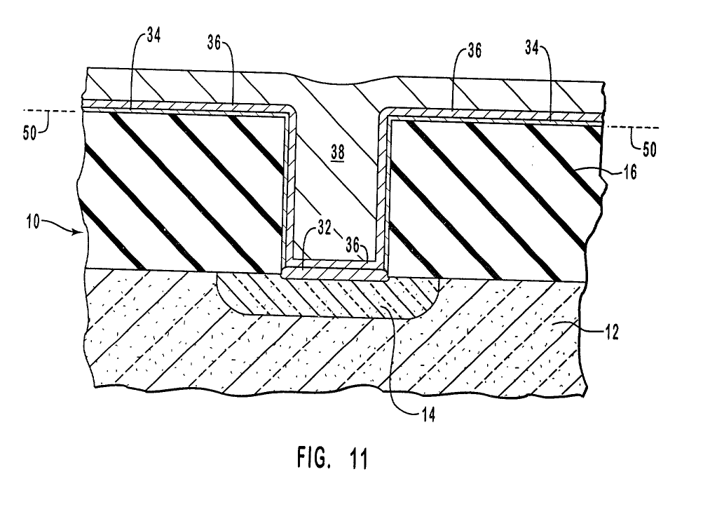

As shown in FIG. 11, a conductive filler material, which comprises in the depicted embodiment a tungsten layer 38, is thereafter deposited using conventional methods. Other conductive filler material than tungsten could alternatively be deposited. For example, aluminum and copper are also suitable. Tungsten layer 38 can also be formed by nucleation without diffusion barrier liner layer 36. A planarization line 50 indicates the result of a subsequent planarizing step so as to isolate tungsten layer 38 within liners 34, 36 circumscribed by BPSG layer 16. The subsequent planarizing step can be conventionally performed, although chemical mechanical planarizing is preferred.

A second embodiment of the inventive method is illustrated in the collection of FIGS. 1, 2, 6, 7, and 9 through 11. In the second embodiment, begin FIG. 2, native oxide layer 20 has been cleaned from source/drain region 14, preferably by an in situ preclean. The in situ preclean can comprise, for instance, an etching process that selectively removes oxygen and carbon from the silicon surface of source/drain region 14. The etching process is typically a low energy process, such as electron cyclotron residence (ECR) or an isotropic downstream etching process. A hydrogen clean is also preferred, such as a process that exposes diatomic hydrogen to semiconductor wafer 10 in situ in a heated environment. After the in situ preclean, semiconductor wafer 10 must remain in a vacuum until a subsequent step of cobalt deposition is conducted.

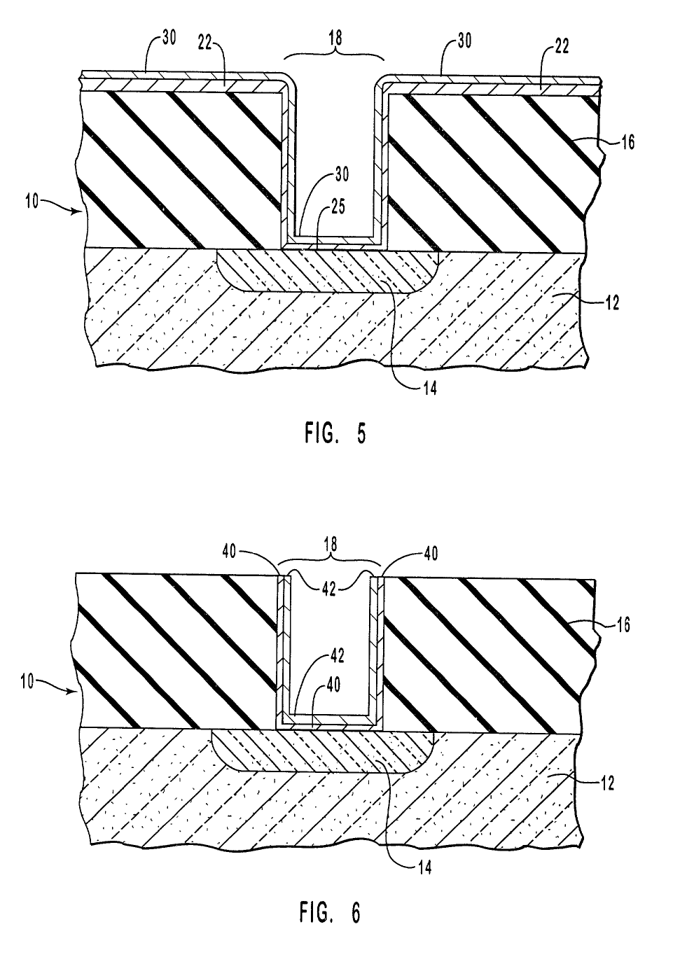

After the in situ preclean, a cobalt seed layer 40 is deposited as shown in FIG. 6, preferably with a thickness in a range from about 2 Å to about 4 Å. A co-deposition of cobalt and silicon is then conducted to result in a primary cobalt and silicon layer 42 with a preferred thickness in a range from about 7 Å to about 14 Å. Primary cobalt and silicon layer 42 can be deposited in any suitable manner, an example of which is sputtering with dual cobalt and silicon targets.

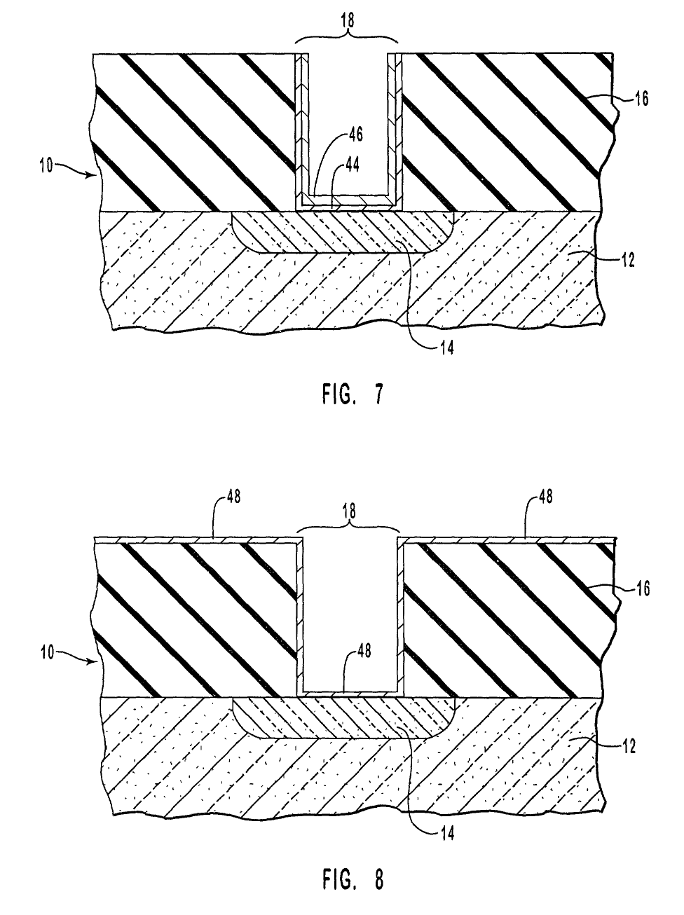

As shown in FIG. 7, cobalt and silicon layer 42 is subjected to a thermal treatment, preferably at a temperature in a range from about 300° C. to 500° C., for a time period in a range from about 1 second to about 60 seconds, and most preferably for a time of about 30 seconds. The thermal treatment forms a composite cobalt and silicon layer 44. Further co-deposition of cobalt and silicon is then conducted while semiconductor wafer 10 is heated to a temperature of about 500° C. to form a secondary cobalt and silicon layer 46 having a thickness in a range from about 50 Å to about 100 Å. The total thickness of the composite cobalt and silicon layer 44 and secondary cobalt and silicon layer 46 in the second embodiment will preferably be thinner than cobalt layer 30 in the first embodiment. This difference in thickness is due to cobalt material in layers 44, 46 of the second embodiment being in direct interface with the silicon material of source/drain region 14, rather being separated from the silicon material of source/drain region 14 by titanium layer 22 seen in FIG. 5 in the first embodiment.

As seen in FIG. 9, a further thermal treatment is subsequently conducted to transform composite cobalt and silicon layer 44 and secondary cobalt and silicon layer 46 into a cobalt silicide region 32. Cobalt suicide region 32 is substantially composed of stoichiometric cobalt silicide. The thermal treatment is preferably an RTP process conducted at a temperature in a range from about 400° C. to about 600° C., for a time period in a range from about to 1 second to about 60 seconds, and most preferably for a time period of about 30 seconds.

When desirable, excess cobalt and silicon which remains unconverted to cobalt silicide can thereafter be removed. For example, it may be necessary to strip cobalt and silicon situated on the sidewall of the interconnect structure opening having a thickness that causes an undesirable level of cusping at the entrance to the interconnect structure opening. The processes as discussed above can be used for stripping the excess unreacted cobalt and silicon, which processes will preferably be selective to cobalt silicide.

In steps performed in each of the first and second embodiments, which steps are depicted in FIGS. 10 and 11, a diffusion barrier liner layer such as titanium nitride diffusion barrier 36 is optionally formed together with an underlying titanium layer 34 and a conductive filler material such as a tungsten layer 38 which is subsequently planarized at planarization line 50 as shown in FIG. 11.

A third embodiment of the inventive method is illustrated in the collection of FIGS. 1, 2, 8, and 9 through 11. In the third embodiment, beginning in FIG. 2, source/drain region 14 has cleaned therefrom native oxide layer 20, preferably by the in situ preclean described above.

After the in situ preclean, a cobalt seed layer 48 seen in FIG. 8 is deposited, preferably with a thickness in a range from about 50 Å to about 100 Å. An anneal is then conducted, preferably as an RTP process having a temperature in a range from about 400° C. to about 600° C., for a time period in a range from about 1 second to about 60 seconds, and most preferably for a time period of about 30 seconds. Excess cobalt may then be stripped, if desired, in the manner discussed above, so as to avoid cusping. The resultant structure is seen in FIG. 9, where cobalt silicide layer 32 has been formed.

Subsequently, as in the first and second embodiments, the structure of FIG. 9 is processed as described above to create the structure seen in FIGS. 10 and 11. A diffusion barrier liner layer, such as titanium nitride diffusion barrier 36 together with an underlying titanium layer 34, may be omitted as an option in the third embodiment. A conductive filler material, such as tungsten layer 38, is deposited and planarized to planarization line 50 to complete an interconnect structure in the form of a tungsten plug contact, which appears substantially as shown in FIG. 11.

The interconnect structure as herein described and embodied resulting from the method of the present invention forms a satisfactory diffusion barrier with a desirably low film thickness disclosed above. The resulting diffusion barrier liner layer on a sidewall of the interconnect structure opening can also be easily etched to further reduce the thickness thereof. The film thickness reduces cusping and incomplete conductive material filling of high aspect ratio contacts, yet the cobalt silicide region provided by the method still provides a desirably low contact resistance and avoids agglomeration. The resulting cobalt silicide contact interface will preferably be a smooth epitaxially grown film having a desirable epitaxial integrity. Furthermore, the cobalt silicide region of the present invention, in the formation thereof, consumes a desirably low amount of silicon from a junction below a contact as described above. An optimally low consumption of junction material minimizes junction leakage so as to be compatible with processes featuring a shallow junction.

The present invention may be embodied in other specific forms without departing from its spirit or essential characteristics. The described embodiments of the novel structure and inventive methods are to be considered in all respects only as illustrated and not restrictive. The scope of the invention is, therefore, indicated by the appended claims rather than by the foregoing description. All changes which come within the meaning and range of equivalency of the claims are to be embraced within their scope.

What is claimed is:

1. A method for forming an interconnect structure, the method comprising:
forming an opening within an insulating layer, the opening extending to and terminating at an electrically active area within a semiconductor substrate, the electrically active area including a junction that extends into the semiconductor substrate to a depth in a range from about 500 Å to about 2000 Å, wherein the insulating layer defines one or more sidewalls of the opening and the semiconductor substrate defines a bottom of the opening;
forming a titanium layer within the opening;
thermally treating the titanium layer to remove an oxide material from the bottom of the opening by absorption into the titanium layer;
forming a cobalt silicide region within the opening and over the semiconductor substrate;
positioning a conductive material within the opening and in contact with the cobalt silicide region, said conductive material filling the opening and extending from the cobalt silicide region above the opening and upon a top surface of the insulating layer;
planarizing the conductive material to form a top surface thereon that is co-planar with the top surface of the insulating layer; and
electrically interconnecting the planar top surface of the conductive material.

2. The method of claim 1, further comprising, prior to positioning the conductive material within the opening, removing a titanium material of the titanium layer from the bottom of the opening.

3. The method of claim 2, wherein oxygen atoms from the oxide material at the bottom of the opening are removed concurrently with removing the titanium material of the titanium layer from the bottom of the opening.

4. The method of claim 1, wherein forming the cobalt silicide region comprises:
forming a cobalt layer within the opening and over the substrate; and
thermally treating the cobalt layer to transform at least a portion of the cobalt layer into the cobalt suicide region, the cobalt silicide region being substantially composed of stoichiometric cobalt silicide.

5. The method of claim 1, wherein removing the oxide material from the bottom of the opening is conducted in an in situ cleaning process.

6. The method of claim 1, wherein forming the cobalt silicide region comprises forming a cobalt seed layer within the opening having a thickness in a range from about 2 Å to about 4Å.

7. The method of claim 6, wherein forming the cobalt silicide region further comprises, after forming the cobalt seed layer, conducting a first co-deposition of cobalt and silicon into the opening to form a primary cobalt and silicon layer.

8. The method of claim 7, wherein the first co-deposition of cobalt and silicon is conducted such that the primary cobalt and silicon layer has a thickness in a range from about 7 Å to about 14 Å.

9. The method of claim 7, wherein forming the cobalt silicide region further comprises:
thermally treating the primary cobalt and silicon layer; and
conducting a second co-deposition of cobalt and silicon into the opening to form a secondary cobalt and silicon layer.

10. The method of claim 9, wherein the second co-deposition of cobalt and silicon is conducted such that the secondary cobalt and silicon layer has a thickness in a range from about 50 Å to about 100 Å.

11. The method of claim 10, wherein forming the cobalt silicide region further comprises thermally treating the secondary cobalt and silicon layer to transform at least a portion thereof into stoichiometric cobalt silicide.

12. The method of claim 9, further comprising, after forming the cobalt silicide region, removing from the secondary cobalt and silicon layer a quantity of cobalt and silicon that has not reacted to form stoichiometric cobalt silicide.

13. The method of claim 4, wherein forming the cobalt layer within the opening is conducted such that the cobalt layer has a thickness in a range from about 50 Å0 to about 100 Å.

14. The method of claim 4, wherein thermally treating the cobalt layer to transform at least a portion of the cobalt layer into a cobalt silicide region includes annealing the substrate and the cobalt layer at a temperature in a range from about 400° C. to about 600° C. and for a time period in a range from about 1 second to about 60 seconds.

15. The method of claim 14, further comprising, after thermally treating the cobalt layer to transform at least a portion of the cobalt layer into a cobalt silicide region, removing from the cobalt layer a quantity of cobalt that has not been transformed into cobalt silicide.

16. The method of claim 1, wherein the junction is a component of a semiconductor device that is selected from the group consisting of a resistor, a capacitor, a diode, and a transistor.

17. The method of claim 1, wherein the conductive material comprises aluminum.

18. The method of claim 17, wherein electrically interconnecting the planar top surface of the conductive material comprises electrically interconnecting the planar top surface of the conductive material with an aluminum metallization.

19. The method of claim 1, wherein the conductive material comprises copper.

20. The method of claim 1, wherein the conductive material comprises tungsten.

21. A method of forming an interconnect structure, the method comprising:
providing an interconnect structure opening extending through an insulating layer to terminate at an active area on a silicon layer of a semiconductor substrate assembly, the active area including a junction extending within the silicon layer to a depth in a range from about 500 Å to about 2000 Å;
removing oxide from a native oxide layer on the silicon layer at a bottom of the interconnect structure opening with an in situ cleaning process;
forming a cobalt seed layer having a thickness in a range from about 2 Å to about 4 Å in the interconnect structure opening;
conducting a first co-deposition of cobalt and silicon into the interconnect structure opening to form a primary cobalt and silicon layer having a thickness in a range from about 7 Å to about 14 Å;
thermally treating the primary cobalt and silicon layer;
conducting a second co-deposition of cobalt and silicon into the interconnect structure opening to form a secondary cobalt and silicon layer having a thickness in a range from about 50 Å to about 100 Å;
annealing the semiconductor substrate assembly to transform at least a portion of the secondary cobalt and silicon layer into a cobalt silicide region that includes stoichiometric cobalt silicide;
removing excess cobalt and silicon from the secondary cobalt and silicon layer that have not been fully transformed into cobalt silicide;
forming a titanium nitride diffusion barrier liner layer in the interconnect structure opening;
filling the interconnect structure opening with a conductive filler material, said conductive filler material filling the interconnect structure opening and extending from the cobalt silicide to above the interconnect structure opening and upon a top surface of the insulating layer;
planarizing the conductive filler material and the titanium nitride diffusion barrier liner layer to form a top surface on each of the conductive filler material and the titanium nitride diffusion barrier liner layer that are each co-planar with the top surface of the insulating layer; and
electrically interconnecting the planar top surface of the conductive filler material.

22. The method of claim 21, wherein the junction is a component of a semiconductor device that is selected from the group consisting of a resistor, a capacitor, a diode, and a transistor.

23. The method of claim 21, wherein the conductive filler material comprises aluminum.

24. The method of claim 23, wherein electrically interconnecting the planar top surface of the conductive filler material comprises electrically interconnecting the planar top surface of the conductive filler material with an aluminum metallization.

25. The method of claim 21, wherein the conductive filler material comprises copper.

26. The method of claim 21, wherein the conductive filler material comprises tungsten.
